(19) United States
(12) Patent Application Publication
(10) Pub. No.: US 2019/0215963 A1
(43) Pub. Date: Jul. 11, 2019

(54) CIRCUIT BOARD, METHOD OF MANUFACTURING CIRCUIT BOARD, AND ELECTRONIC DEVICE

(71) Applicant: FUJITSU LIMITED, Kawasaki-shi (JP)

(72) Inventors: Tomoyuki Akahoshi, Atsugi (JP); Hideaki Nagaoka, Atsugi (JP); Daisuke Mizutani, Sagamihara (JP)

(73) Assignee: FUJITSU LIMITED, Kawasaki-shi (JP)

(21) Appl. No.: 16/354,556

(22) Filed: Mar. 15, 2019

Related U.S. Application Data
(63) Continuation of application No. PCT/JP2017/046161, filed on Dec. 22, 2017.

(30) Foreign Application Priority Data
Jan. 5, 2017 (JP) 2017-000691

(51) Int. Cl. H05K 1/16; H05K 1/18; H05K 1/11; H05K 3/46; H01G 4/33

(52) U.S. Cl. CPC H05K 1/162; H05K 1/181; H01L 23/49816; H05K 3/4644; H01G 4/33; H05K 1/115

(57) ABSTRACT

A circuit board includes a first capacitor that includes a first dielectric layer, a first conductor layer disposed on a first surface of the first dielectric layer, and a second conductor layer disposed on a second surface of the first dielectric layer opposite to the first surface, a first insulating layer that is bonded to the first surface side with a first adhesive layer and has a higher elastic modulus than the first adhesive layer, and a second insulating layer that is bonded to the second surface side with a second adhesive layer and has a higher elastic modulus than the second adhesive layer.

### CROSS-REFERENCE TO RELATED APPLICATION

This application is a continuation application of International Application PCT/2017/046161 filed on Dec. 22, 2017 and designated the U.S., the entire contents of which are incorporated herein by reference. The International Application PCT/2017/046161 is based upon and claims the benefit of priority of the prior Japanese Patent Application No. 2017-000691, filed on Jan. 5, 2017, the entire contents of which are incorporated herein by reference.

### FIELD

The embodiments discussed herein are related to a circuit board, a method of manufacturing a circuit board, and an electronic device.

### BACKGROUND

A technique of incorporating a capacitor in a circuit board is known. The capacitor has a structure in which a dielectric layer using a predetermined material is sandwiched between a pair of conductor layers to be an upper electrode and a lower electrode. It is known to coat such a capacitor with an insulating resin, to incorporate a capacitor covered with an insulating resin in the board, and the like.

If the rigidity and strength of the circuit board are insufficient at the time of manufacturing the circuit board or an electronic device using the circuit board or when using the circuit board or the electronic device, cracks may occur in the dielectric layer of the incorporated capacitor or cracks or peeling may occur between the dielectric layer and the conductor layer. Damage to the capacitor such as cracks or peeling may lower the electrostatic capacitance thereof and possibly degrade the performance and reliability of the circuit board containing the capacitor.

The following is a reference document.

### [Document 1] Japanese Laid-open Patent Publication No. 2009-267310.

### SUMMARY

According to an aspect of the embodiments, a circuit board includes a first capacitor that includes a first dielectric layer, a first conductor layer disposed on a first surface of the first dielectric layer, and a second conductor layer disposed on a second surface of the first dielectric layer opposite to the first surface, a first insulating layer that is bonded to the first surface side with a first adhesive layer and has a higher elastic modulus than the first adhesive layer, and a second insulating layer that is bonded to the second surface side with a second adhesive layer and has a higher elastic modulus than the second adhesive layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating an example of a circuit board according to a first embodiment;

FIG. 2 is a diagram illustrating a first example of a circuit board according to a second embodiment;

FIG. 3 is a diagram illustrating a second example of the circuit board according to the second embodiment;

FIG. 4 is a diagram illustrating an example of a circuit board according to a third embodiment;

FIGS. 5A, 5B, and 5C are diagrams (part 1) illustrating an example of a method for forming a circuit board according to a fourth embodiment;

FIGS. 6A, 6B, and 6C are diagrams (part 2) illustrating an example of the method for forming the circuit board according to the fourth embodiment;

FIGS. 7A, 7B, and 7C are diagrams (part 3) illustrating an example of the method for forming the circuit board according to the fourth embodiment;

FIGS. 8A and 8B are diagrams (part 1) illustrating another example of the method for forming the circuit board according to the fourth embodiment;

FIGS. 9A and 9B are diagrams (part 2) illustrating another example of the method for forming the circuit board according to the fourth embodiment;

FIGS. 10A and 10B are diagrams (part 3) illustrating another example of the method for forming the circuit board according to the fourth embodiment;

FIG. 11 is a diagram illustrating a first example of a circuit board according to a fifth embodiment;

FIG. 12 is a diagram illustrating a second example of the circuit board according to the fifth embodiment;

FIG. 13 is a diagram illustrating a third example of the circuit board according to the fifth embodiment;

FIG. 14 is a diagram illustrating a fourth example of the circuit board according to the fifth embodiment;

FIG. 15 is a diagram illustrating an example of an electronic device according to a sixth embodiment; and

FIG. 16 is an explanatory diagram of an electronic apparatus according to a seventh embodiment.

### DESCRIPTION OF EMBODIMENTS

Regarding a circuit board on which electronic components such as semiconductor apparatuses are mounted, as a method for reducing power supply noise, a capacitor (also referred to as a thin film capacitor) including a dielectric layer containing ceramic or the like as a main component and a pair of conductor layers (electrode layers) sandwiching the dielectric layer is incorporated in the circuit board. In a circuit board incorporating a capacitor, for example, stress may be generated by heat applied when the circuit board is formed or when the electronic components are mounted on the formed circuit board, alternatively, by heat applied during use or testing of the formed circuit board or an electronic device using the circuit board. If the rigidity and strength of the circuit board are insufficient with respect to the generated stress, cracks may occur in the dielectric layer of the incorporated capacitor, cracks or peeling may occur between the dielectric layer and the electrode layer, and the capacitor may be damaged. If the thickness of the dielectric layer is reduced in order to improve the performance of the capacitor, damage to the capacitor such as cracks and peeling is more likely to occur. Damage to the capacitor may lower the electrostatic capacitance thereof and possibly degrade the performance and reliability of the circuit board containing the capacitor.

In consideration of the above points, here, the structure illustrated as the embodiment is adopted to suppress the damage to the capacitor incorporated in the circuit board. First, a first embodiment will be described.

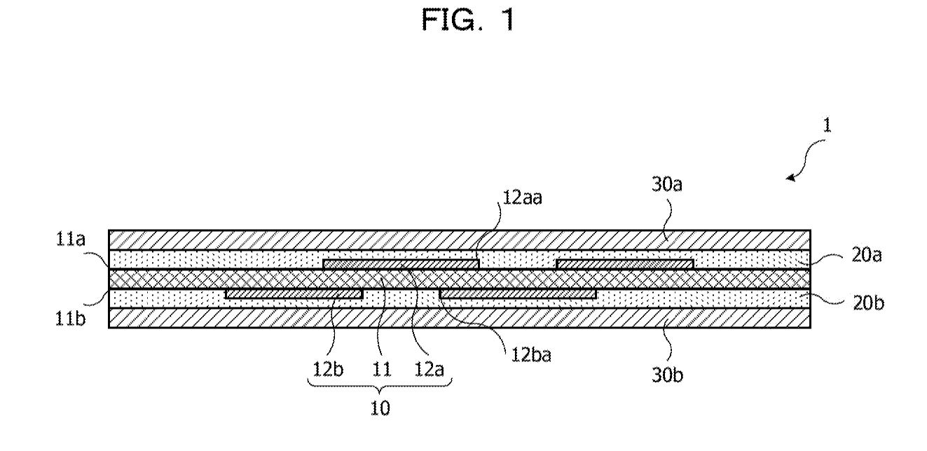

FIG. 1 is a diagram illustrating an example of a circuit board according to the first embodiment. FIG. 1 schematically illustrates a cross section of a main part of an example of a circuit board according to the first embodiment. A circuit board 1 illustrated in FIG. 1 has a capacitor 10, an adhesive layer 20a, an adhesive layer 20b, an insulating layer 30a, and an insulating layer 30b.

The capacitor 10 has a dielectric layer 11, an electrode layer 12a (conductor layer) provided on one surface 11a of the dielectric layer 11, and an electrode layer 12b (conductor layer) provided on the other surface 11b (the surface opposite to the surface 11a) of the dielectric layer 11.

Various dielectric materials are used for the dielectric layer 11. For example, a ceramic material is used for the dielectric layer 11. As the ceramic material of the dielectric layer 11, various high dielectric materials such as barium titanate (BaTiO₃; BTO) or the like may be used. As the ceramic material of the dielectric layer 11, high dielectric materials such as barium strontium titanate (BaₓSr₁₋ₓTiO₃; BSTO) to which BTO is doped with strontium (Sr), strontium titanate (SrTiO₃; STO), lead zirconate titanate (Pb(Zr, Ti)O₃; PZT), PZT(PLZT) to which lanthanum (La) is doped may be used.

Various conductor materials are used for the electrode layer 12a and the electrode layer 12b. For example, a metal material is used for the electrode layer 12a and the electrode layer 12b. As the metal material of the electrode layer 12a and the electrode layer 12b, copper (Cu), nickel (Ni), or the like may be used. The electrode layer 12a and the electrode layer 12b are each patterned into a predetermined shape. For example, an opening 12aa and an opening 12ba are respectively provided in the electrode layer 12a and the electrode layer 12b so that a portion where the electrode layer 12a and the electrode layer 12b overlap (oppose) with the dielectric layer 11 interposed therebetween is formed. The opening 12aa of the electrode layer 12a is provided to provide a conductor via (described later) penetrating the electrode layer 12a and the dielectric layer 11 and connecting to the electrode layer 12b. The opening 12ba of the electrode layer 12b is provided to provide a conductor via (described later) penetrating the electrode layer 12b and the dielectric layer 11 and connecting to the electrode layer 12a. In use of the circuit board 1, one of the electrode layer 12a and the electrode layer 12b is set to the power supply potential and the other is set to the GND potential, and a portion where the electrode layer 12a and the electrode layer 12b overlap via the dielectric layer 11 functions as a capacitor.

The insulating layer 30a is bonded to the one surface 11a side of the dielectric layer 11 of the capacitor 10 with the adhesive layer 20a, and the insulating layer 30b is bonded to the other surface 11b side of the dielectric layer 11 with the adhesive layer 20b. In the circuit board 1 illustrated in FIG. 1, the adhesive layer 20a is provided on the surface 11a of the dielectric layer 11 so as to cover the electrode layer 12a provided on the surface 11a, and the capacitor 10 (the surface 11a thereof) and the insulating layer 30a are bonded with the adhesive layer 20a. Similarly, the adhesive layer 20b is provided on the surface 11b of the dielectric layer 11 so as to cover the electrode layer 12b provided on the surface 11b, and the capacitor 10 (the surface 11b thereof) and the insulating layer 30b are bonded with the adhesive layer 20b.

Here, as the insulating layer 30a, an insulating material having a higher elastic modulus than the adhesive layer 20a, for example, an insulating material having high rigidity and Young's modulus is used. As the insulating layer 30b, an insulating material having a higher elastic modulus than the adhesive layer 20b, for example, an insulating material having high rigidity and Young's modulus is used.

For the adhesive layer 20a and the adhesive layer 20b, various organic or inorganic adhesive materials whose elastic modulus is lower than those of the insulating layers 30a and 30b are used, respectively. For example, an epoxy resin-based adhesive material is used for the adhesive layer 20a and the adhesive layer 20b. Other than this, as the adhesive layer 20a and the adhesive layer 20b, various adhesive materials such as an acrylic resin type, a polyethylene terephthalate resin type, a phenol resin type, a silicone rubber type, a silicate type or the like may be used as long as the elastic modulus is lower than those of the insulating layers 30a and 30b. In addition, the adhesive material of the adhesive layer 20a and the adhesive layer 20b may contain various additives and inorganic or organic type surface insulating fillers.

As the insulating layer 30a and the insulating layer 30b, various insulating materials having higher elastic modulus than the adhesive layer 20a and the adhesive layer 20b are used, respectively. For example, an insulating material containing glass or glass is used for the insulating layer 30a and the insulating layer 30b. In addition, an insulating material containing a resin or a resin, such as a polyimide resin or a polyimide resin, is used for the insulating layer 30a and the insulating layer 30b. For example, a glass plate, a sheet impregnated with glass fiber or glass cloth in a resin, a polyimide resin sheet, a resin sheet containing a polyimide resin as a main component, or the like is used for the insulating layer 30a and the insulating layer 30b.

In order to satisfy a predetermined magnitude relationship with respect to the elastic modulus of each other, the combination of the materials of the adhesive layer 20a and the adhesive layer 20b, the materials of the insulating layer 30a and the insulating layer 30b, the combination of the materials of the adhesive layer 20a and the insulating layer 30a, and the combination of the materials of the adhesive layer 20b and the insulating layer 30b are set.

The adhesive layer 20a and the adhesive layer 20b are not necessarily formed by using the same adhesive material. In addition, the insulating layer 30a and the insulating layer 30b are not necessarily formed by using the same insulating material.

As described above, in the circuit board 1, the capacitor 10 is sandwiched between the insulating layer 30a and the insulating layer 30b having a higher elastic modulus than those of the insulating layer 30a and the insulating layer 30b via the adhesive layer 20a and the adhesive layer 20b. This increases the rigidity and strength of the circuit board 1.

By increasing the rigidity and strength of the circuit board 1, damage of the capacitor 10 due to stress caused by heat at the time of forming a circuit board as a basic structure and mounting electronic components on the formed circuit board, or during use or testing of the formed circuit board or an electronic device using the circuit board is suppressed. That is, by increasing the rigidity and strength of the circuit board 1, damage of the capacitor 10 such as cracks occurring in the dielectric layer 11, and cracks and peeling occurring between the dielectric layer 11 and the electrode layer 12a or the electrode layer 12b is suppressed. As a result, reduction in the electrostatic capacitance due to damage of the capacitor 10 is suppressed. Even in a case where the electrostatic capacitance of the capacitor 10 is increased by reducing the thickness of the dielectric layer 11, the rigidity and the strength of the circuit board 1 are increased, and damage to the capacitor 10 is suppressed thereby to maintain the high electrostatic capacitance of the capacitor 10.

According to the above configuration, it is possible to effectively suppress deterioration in the performance and reliability of the circuit board 1 having the capacitor 10 therein and the circuit board having the capacitor 10 as a basic structure. In the circuit board 1, a material having a low thermal expansion coefficient or a material having a low curing shrinkage ratio may be used as the adhesive layer 20a and the adhesive layer 20b for bonding the insulating layer 30a and the insulating layer 30b having relatively a high elastic modulus to the capacitor 10. When such a material is used, it is possible to reduce stress generated in the capacitor 10 due to expansion during heating of the adhesive layer 20a and the adhesive layer 20b and subsequent shrinkage during cooling so as to suppress damage to the capacitor 10. As a material having a low coefficient of thermal expansion or a material having a low curing shrinkage ratio which may be used for the adhesive layer 20a and the adhesive layer 20b, various resin materials such as an epoxy resin type, acrylic resin type, and polyethylene terephthalate resin. In addition, a filler such as silica may be contained in various resin materials (not necessary a material having a low thermal expansion coefficient or a material having a low curing shrinkage ratio) so as to relatively reduce the content of the resin component to suppress thermal expansion or curing shrinkage.

Next, a second embodiment will be described. Here, an example of a circuit board having the basic structure of the circuit board 1 described in the first embodiment will be described as a second embodiment.

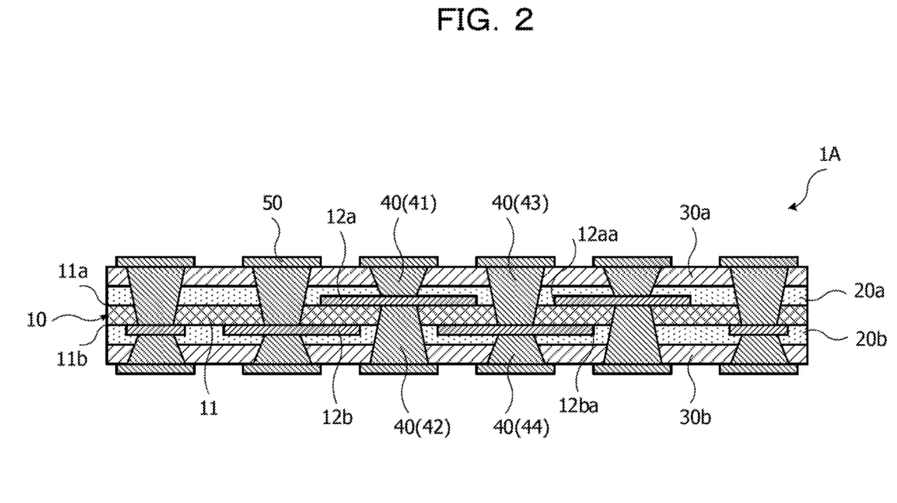

FIG. 2 is a diagram illustrating a first example of a circuit board according to the second embodiment. FIG. 2 schematically illustrates a cross section of a main part of the first example of the circuit board according to the second embodiment. A circuit board 1A illustrated in FIG. 2 has a conductor via 40 connected to non-overlapping portions of the electrode layer 12a and the electrode layer 12b provided on the surface 11a and the surface 11b of the capacitor 10, and a conductor layer 50 provided on the insulating layer 30a and the insulating layer 30b and connected to the conductor via 40.

The circuit board 1A includes a conductor via 41 penetrating the insulating layer 30a and the adhesive layer 20a and connected to the electrode layer 12a, as the conductor via 40 to be connected to the electrode layer 12a. Further, the circuit board 1A includes a conductor via 42 penetrating the insulating layer 30b, the adhesive layer 20b, the opening 12ba of the electrode layer 12b, the dielectric layer 11 and connected to the electrode layer 12a, as the conductor via 40 to be connected to the electrode layer 12a. In addition, the circuit board 1A includes a conductor via 43 penetrating the insulating layer 30a, the adhesive layer 20a, the opening 12aa of the electrode layer 12a, and the dielectric layer 11 and connected to the electrode layer 12b, as the conductor via 40 to be connected to the electrode layer 12b. Further, the circuit board 1A includes a conductor via 44 penetrating the insulating layer 30b and the adhesive layer 20b and connected to the electrode layer 12b, as the conductor via 40 to be connected to the electrode layer 12b.

The conductor layer 50 of the circuit board 1A is provided on the insulating layer 30a and the insulating layer 30b so as to be connected to the conductor via 41, the conductor via 42, the conductor via 43, and the conductor via 44, respectively. The conductor layer 50 is formed on the insulating layer 30a and the insulating layer 30b so as to have a predetermined wiring pattern shape.

For example, the conductor via 40 and the conductor layer 50 of the circuit board 1A are obtained by forming holes which communicate with the electrode layer 12a and the electrode layer 12b by laser processing on the circuit board 1 (FIG. 1) having the basic structure, forming conductors in the holes and the surface of the circuit board 1 by plating, and patterning the conductors on the surface. The conductor formed in the hole becomes the conductor via 40, and the patterned conductor on the surface becomes the conductor layer 50.

Here, as the conductor via 40, a filled via filled with a conductor material in the hole is exemplified, but a conformal via formed on the inner wall of the hole may be formed. In this case, a cavity such as an epoxy resin or the like may be filled in the cavity remaining in the center portion of the conductor via 40 formed on the inner wall of the hole.

During use or testing of the circuit board 1A, one of the electrode layer 12a and the electrode layer 12b is set to the power supply potential and the other is set to the GND potential through the conductor layer 50 and the conductor via 40, and an overlapping portion of the electrode layer 12a and the electrode layer 12b via the dielectric layer 11 functions as a capacitor.

Using the circuit board 1 illustrated in FIG. 1 as a basic structure, for example, as illustrated in FIG. 2, the circuit board 1A having the conductor via 40 and the conductor layer 50 is obtained. In the circuit board 1A, since the capacitor 10 is sandwiched between the insulating layer 30a and the insulating layer 30b via the adhesive layer 20a and the adhesive layer 20b to increase the rigidity and strength, damage to the capacitor 10 is suppressed. As a result, the circuit board 1A having excellent performance and reliability is realized.

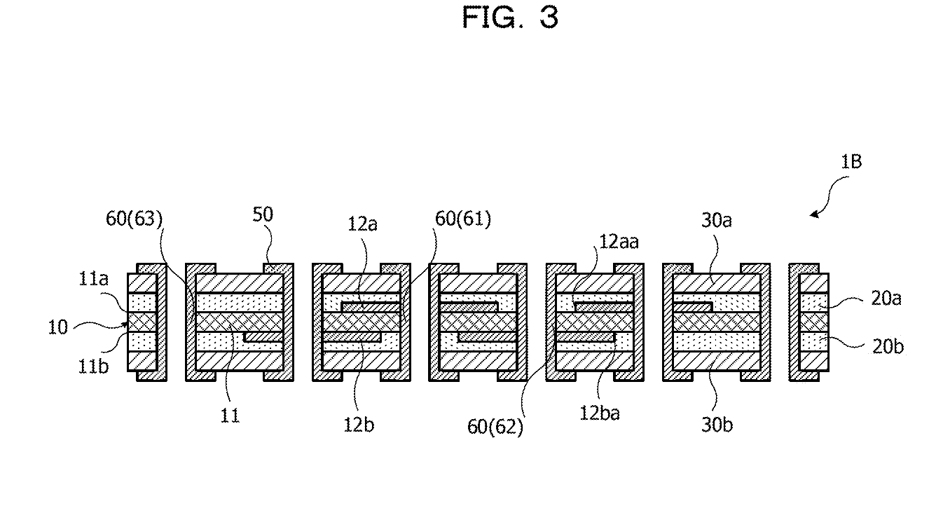

In addition, FIG. 3 is a diagram illustrating a second example of the circuit board according to the second embodiment. FIG. 3 schematically illustrates a cross section of a main part of the second example of the circuit board according to the second embodiment. A circuit board 1B illustrated in FIG. 3 further includes a conductor via 60 penetrating from one insulating layer 30a to the other insulating layer 30b and the conductor layer 50 provided on the insulating layer 30a and the insulating layer 30b and connected to the conductor via 60.

The circuit board 1B includes a conductor via 61 and a conductor via 62 penetrating the non-overlapping portions of the electrode layer 12a and the electrode layer 12b, as the conductor via 60, and a conductor via 63 penetrating portions where neither the electrode layer 12a nor the electrode layer 12b exist.

The conductor via 61 penetrates the insulating layer 30a, the adhesive layer 20a, the electrode layer 12a, the dielectric layer 11, the opening 12ba of the electrode layer 12b, the adhesive layer 20b, and the insulating layer 30b. The conductor via 62 penetrates the insulating layer 30a, the adhesive layer 20a, the opening 12aa of the electrode layer 12a, the dielectric layer 11, the electrode layer 12b, the adhesive layer 20b, and the insulating layer 30b. The conductor via 61 is connected to the electrode layer 12a provided on the surface 11a of the capacitor 10, and the conductor via 62 is connected to the electrode layer 12b provided on the surface 11b of the capacitor 10. In addition, the conductor via 63 penetrates the insulating layer 30a, the adhesive layer 20a, the dielectric layer 11, the adhesive layer 20b, and the insulating layer 30b at portions where neither the electrode layer 12a nor the electrode layer 12b exist.

The conductor layer 50 of the circuit board 1B is provided on the insulating layer 30a and the insulating layer 30b so as to be connected to the conductor via 61, the conductor via 62, and the conductor via 63, respectively. The conductor layer 50 is formed on the insulating layer 30a and the insulating layer 30b so as to have a predetermined wiring pattern shape.

For example, the conductor via 60 and the conductor layer 50 of the circuit board 1B are obtained by forming a hole penetrating from the insulating layer 30a to the insulating layer 30b by drilling on the circuit board 1 (FIG. 1) having the basic structure, forming a conductor by plating on the inner wall of the hole and the surface of the circuit board 1, and patterning the conductor on the surface. The conductor formed on the inner wall of the hole becomes the conductor via 60, and the patterned conductor on the surface becomes the conductor layer 50.

A cavity may be left in the center portion of the hole in which the conductor via 60 is formed on the inner wall or a resin (not illustrated) such as an epoxy resin may be filled. In the case of filling with a resin, after filling, a conductor may be further formed by plating on the conductor via 60 in the hole and on the resin inside the hole (so-called lid plating). In addition, here, as the conductor via 60, a conformal via formed on the inner wall of the hole is exemplified, but a filled via filled with a conductor material may be formed in the hole.

During use or testing of the circuit board 1B, one of the electrode layer 12a and the electrode layer 12b is set to the power supply potential and the other is set to the GND potential through the conductor layer 50 and the conductor via 60, and an overlapping portion of the electrode layer 12a and the electrode layer 12b via the dielectric layer 11 functions as a capacitor.

Using the circuit board 1 illustrated in FIG. 1 as a basic structure, for example, as illustrated in FIG. 3, the circuit board 1B having the conductor via 60 and the conductor layer 50 is obtained. In the circuit board 1B, since the capacitor 10 is sandwiched between the insulating layer 30a and the insulating layer 30b via the adhesive layer 20a and the adhesive layer 20b to increase the rigidity and strength, damage to the capacitor 10 is suppressed. As a result, the circuit board 1B having excellent performance and reliability is realized.

In the circuit board 1A and the circuit board 1B, in the adhesive layer 20a and the adhesive layer 20b, physical property values such as dielectric permittivity have little influence on the electrical characteristics of the circuit board 1A and the circuit board 1B as compared with the insulating layer 30a and the insulating layer 30b on which the conductor layer 50 is formed. Therefore, various types of adhesive materials may be used for the adhesive layer 20a and the adhesive layer 20b as long as the materials have adhesion. For the adhesive layer 20a and the adhesive layer 20b, materials may be selected with more emphasis on adhesion (adhesive strength) than electrical characteristics.

Next, a third embodiment will be described. Here, another example of a circuit board having the basic structure of the circuit board 1 described in the first embodiment will be described as the third embodiment.

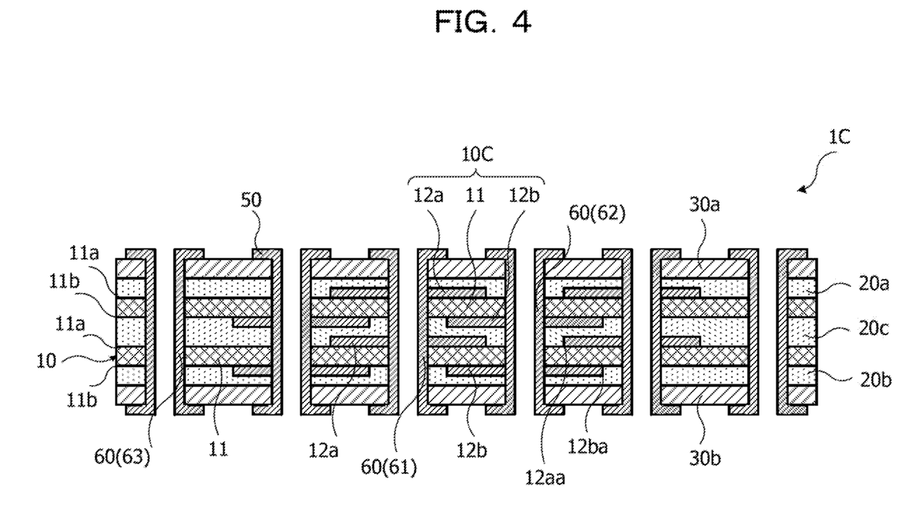

FIG. 4 is a diagram illustrating an example of a circuit board according to the third embodiment. FIG. 4 schematically illustrates a cross section of a main part of an example of the circuit board according to the third embodiment. A circuit board 1C illustrated in FIG. 4 has two layers of the capacitors 10 and capacitors 10C provided between the insulating layer 30a and the insulating layer 30b. The circuit board 1C further includes the conductor via 60 penetrating from one insulating layer 30a to the other insulating layer 30b and the conductor layer 50 provided on the insulating layer 30a and the insulating layer 30b and connected to the conductor via 60.

Like the capacitor 10, the capacitor 10C includes the dielectric layer 11, and the electrode layer 12a and the electrode layer 12b provided on one surface 11a and the other surface 11b of the dielectric layer 11, respectively. For example, another layer of the capacitor 10C is provided between the capacitor 10 and the insulating layer 30a bonded to the surface 11a side of the capacitor 10 with the adhesive layer 20a in the circuit board 1 illustrated in FIG. 1. The insulating layer 30a is bonded to the capacitor 10C (the surface 11a thereof) with the adhesive layer 20a. The capacitor 10C (the surface 11b thereof) and the capacitor 10 (the surface 11a thereof) are bonded with an adhesive layer 20c interposed therebetween. Like the adhesive layer 20a and the adhesive layer 20b, various organic or inorganic adhesive materials are used for the adhesive layer 20c.

The circuit board 1C includes a conductor via 61 and a conductor via 62 penetrating the non-overlapping portions of the electrode layer 12a and the electrode layer 12b of two layers of the capacitors 10 and the capacitors 10C, as the conductor via 60, and a conductor via 63 penetrating portions where neither the electrode layer 12a nor the electrode layer 12b exist. The conductor via 61 is connected to both the electrode layers 12a of the capacitor 10 and the capacitor 10C, and the conductor via 62 is connected to both the electrode layers 12b of the capacitor 10 and the capacitor 10C.

The conductor layer 50 of the circuit board 1C is provided on the insulating layer 30a and the insulating layer 30b so as to be connected to the conductor via 61, the conductor via 62, and the conductor via 63, respectively. The conductor layer 50 is formed on the insulating layer 30a and the insulating layer 30b so as to have a predetermined wiring pattern shape.

For example, the conductor via 60 and the conductor layer 50 of the circuit board 1C are obtained by forming a hole by drilling on the circuit board 1 (FIG. 1) having the basic structure to which the capacitor 10C and the adhesive layer 20c are added, forming a conductor by plating and patterning the conductor. The conductor formed on the inner wall of the hole becomes the conductor via 60, and the patterned conductor on the insulating layer 30a and the insulating layer 30b becomes the conductor layer 50.

A cavity may be left in the center portion of the hole in which the conductor via 60 is formed on the inner wall or a resin (not illustrated) such as an epoxy resin may be filled. In the case of filling with a resin, after filling, a conductor may be further formed by plating on the conductor via 60 in the hole and on the resin inside the hole. In addition, here, as the conductor via 60, a conformal via formed on the inner wall of the hole is exemplified, but a filled via filled with a conductor material may be formed in the hole.

During use or testing of the circuit board 1C, one of the electrode layer 12a and the electrode layer 12b is set to the power supply potential and the other is set to the GND potential through the conductor layer 50 and the conductor via 60, and an overlapping portion of the electrode layer 12a and the electrode layer 12b via the dielectric layer 11 functions as a capacitor.

With the circuit board 1 having the capacitor 10 illustrated in FIG. 1 as a basic structure, for example, as illustrated in FIG. 4, the circuit board 1C having another layer of the capacitor 10C, the conductor via 60 and the conductor layer 50 is obtained. In the circuit board 1C, the capacitor 10 and the capacitor 10C bonded with the adhesive layer 20c are sandwiched between the insulating layer 30a and the insulating layer 30b via the adhesive layer 20a and the adhesive layer 20b to increase the rigidity and strength, damage to the capacitor 10 and the capacitor 10C is suppressed. As a result, the circuit board 1C having excellent performance and reliability is realized.

In the circuit board 1C, for the adhesive layer 20c for bonding the capacitor 10 and the capacitor 10C, an adhesive material having the same elastic modulus as the adhesive layer 20a and the adhesive layer 20b may be used, or an adhesive material having a higher elastic modulus than the adhesive layer 20a and the adhesive layer 20b may be used. In addition, for the adhesive layer 20c, an adhesive material having the same elastic modulus as the insulating layer 30a and the insulating layer 30b may be used, or an adhesive material having a higher elastic modulus than the insulating layer 30a and the insulating layer 30b may be used. By providing such the adhesive layer 20c between the capacitor 10 and the capacitor 10C, the rigidity and strength of the circuit board 1C may be improved.

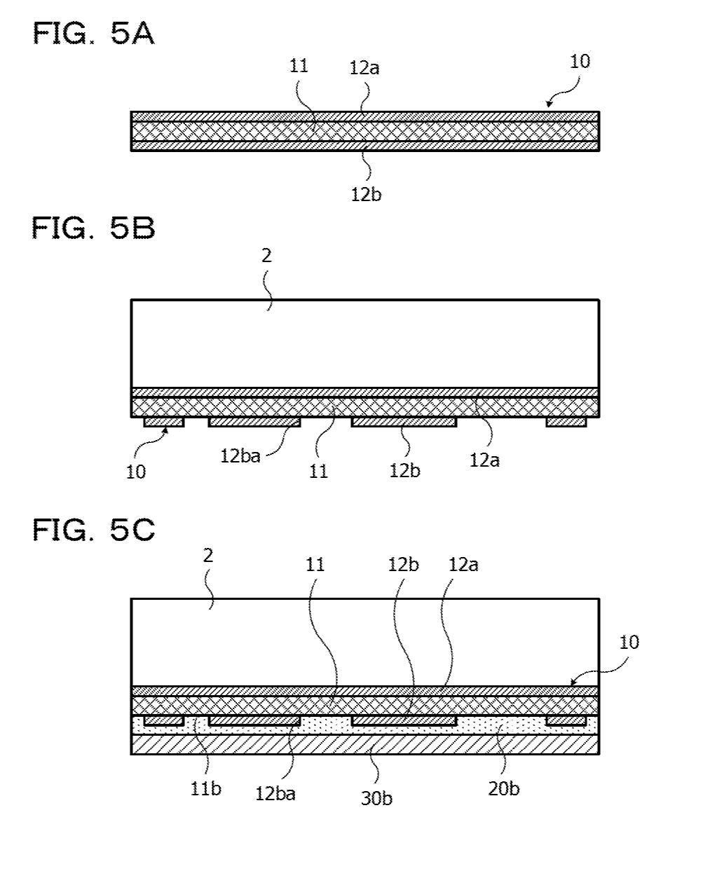

Next, a fourth embodiment will be described. Here, an example of a method of forming a circuit board will be described as the fourth embodiment. FIGS. 5 to 7 are diagrams illustrating an example of a method for forming a circuit board according to the fourth embodiment. FIGS. 5A to 5C, 6A to 6C, and 7A to 7C schematically illustrate a cross section of a main part of each step in an example of forming the circuit board according to the fourth embodiment, respectively.

First, as illustrated in FIG. 5A, the capacitor 10 in which the dielectric layer 11 is sandwiched between the electrode layer 12a and the electrode layer 12b is prepared. For example, the dielectric layer 11 containing BTO or BTO as a main component is formed by sintering on one electrode layer 12a containing Ni or Cu or Ni or Cu as a main component and then the other electrode layer 12b containing Cu or Cu as a main component is coated thereon. By such a method, the capacitor 10 as illustrated in FIG. 5A is obtained. The thickness of the dielectric layer 11 of the capacitor 10 is, for example, 0.5 μm to 2 μm. The thicknesses of the electrode layer 12a and the electrode layer 12b are, for example, 10 μm to 30 μm, respectively.

For example, as illustrated in FIG. 5B, the prepared capacitor 10 is attached to a base board 2 with one electrode layer 12a facing the base board 2 side, and the other electrode layer 12b is patterned by etching or the like. By this patterning, the electrode layer 12b having the opening 12ba formed in a predetermined portion is formed.

Patterning of the electrode layer 12b may be performed without being attached to the base board 2. In addition, in obtaining the capacitor 10 of FIG. 5A, the electrode layer 12b may be patterned as illustrated in FIG. 5B by forming the electrode layer 12a on the base board 2, forming the dielectric layer 11 on the electrode layer 12a, further forming the electrode layer 12b on the electrode layer 12a.

After patterning the electrode layer 12b, as illustrated in FIG. 5C, the adhesive layer 20b is formed on the capacitor 10 (the surface 11b thereof) so as to cover the patterned electrode layer 12b. As the adhesive layer 20b, various kinds of adhesive materials such as an epoxy resin and the like as described above are used. The adhesive layer 20b is formed, for example, by applying a liquid or paste-like adhesive material onto the capacitor 10 or by attaching a sheet-like adhesive material onto the capacitor 10.

After forming the adhesive layer 20b, as illustrated in FIG. 5C, the insulating layer 30b having a higher elastic modulus than the adhesive layer 20b is formed on the adhesive layer 20b. As the insulating layer 30b, various insulating materials such as glass, a polyimide resin, and the like as described above are used. The insulating layer 30b is formed, for example, by attaching a sheet-like insulating material onto the adhesive layer 20b by applying pressure and heating.

As a result, the insulating layer 30b is bonded to the capacitor 10 with the adhesive layer 20b. The thickness of the adhesive layer 20b is, for example, 50 μm to 100 μm. The thickness of the insulating layer 30b is, for example, 50 μm to 100 μm.

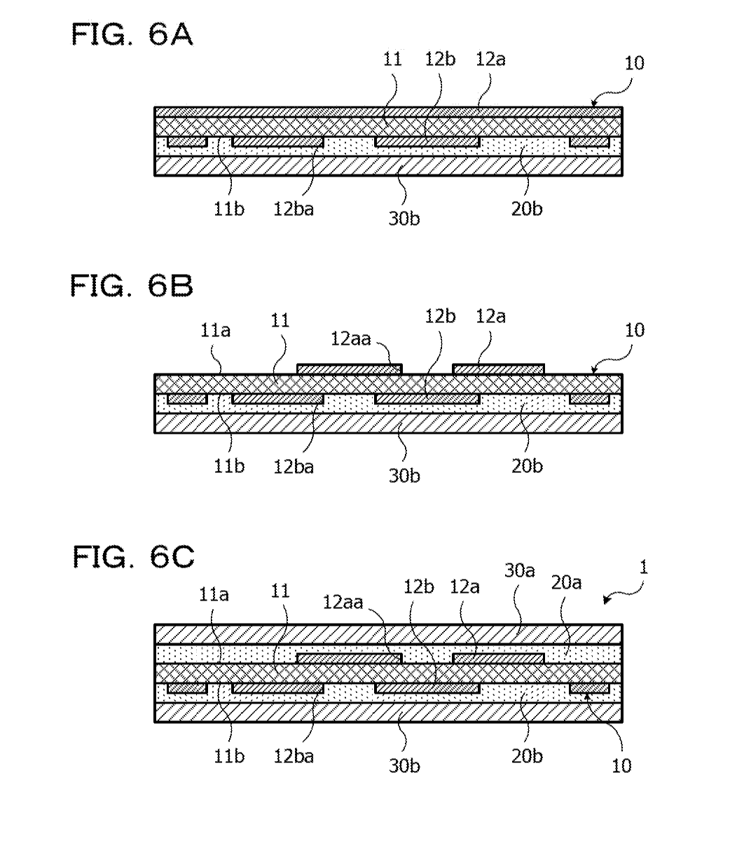

After bonding the insulating layer 30b with the adhesive layer 20b, the base board 2 is peeled off as illustrated in FIG. 6A. After separation of the base board 2, the other electrode layer 12a of the capacitor 10 is patterned by etching or the like as illustrated in FIG. 6B. By this patterning, the electrode layer 12a having the opening 12aa formed in a predetermined portion is formed. After the step of FIG. 6A, patterning of the electrode layer 12a may be performed after the capacitor 10 is attached to the base board with the electrode layer 12b facing the base board side.

After patterning the electrode layer 12a, as illustrated in FIG. 6C, the adhesive layer 20a is formed on the capacitor 10 (the surface 11a thereof) so as to cover the patterned electrode layer 12a. As the adhesive layer 20a, various kinds of adhesive materials such as an epoxy resin and the like as described above are used. The adhesive layer 20a is formed, for example, by applying a liquid or paste-like adhesive material onto the capacitor 10 or by attaching a sheet-like adhesive material onto the capacitor 10.

After forming the adhesive layer 20a, as illustrated in FIG. 6C, the insulating layer 30a having a higher elastic modulus of than the adhesive layer 20a is formed on the adhesive layer 20a. As the insulating layer 30a, various insulating materials such as glass, a polyimide resin, and the like as described above are used. The insulating layer 30a is formed, for example, by attaching a sheet-like insulating material onto the adhesive layer 20a by applying pressure and heating.

As a result, the insulating layer 30a is bonded to the capacitor 10 with the adhesive layer 20a. The thickness of the adhesive layer 20a is, for example, 50 μm to 100 μm. The thickness of the insulating layer 30a is, for example, 50 μm to 100 μm.

By the steps illustrated in FIGS. 5A to 5C and FIGS. 6A to 6C, the circuit board 1 (FIG. 1) described in the first embodiment is obtained. The circuit board 1 obtained in this way is used, and a circuit board having the basic structure is formed.

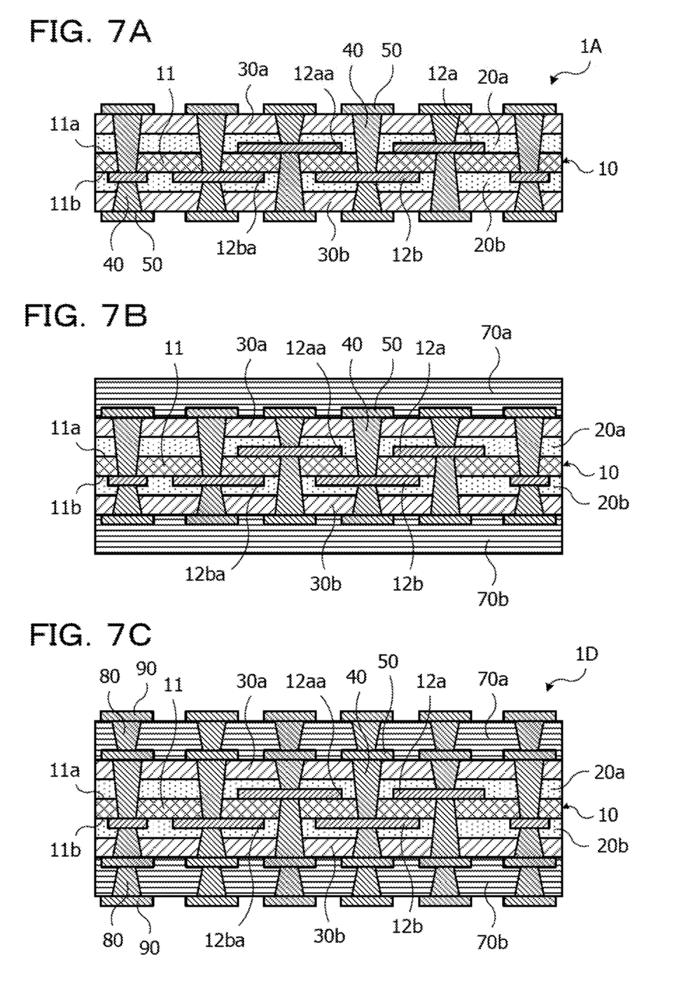

For example, as illustrated in FIG. 7A, the conductor via 40 connected to the non-overlapping portions of the electrode layer 12a and the electrode layer 12b, and the conductor layer 50 connected to the conductor via 40 are formed. The conductor via 40 and the conductor layer 50 illustrated in FIG. 7A are formed, for example, as follows. First, holes communicating with the electrode layer 12a and the electrode layer 12b are formed by laser processing on the circuit board 1 (FIG. 1) having the basic structure. The diameter of the hole is, for example, 50 μm to 250 μm. Next, electroless plating or electrolytic plating is performed, and conductors are formed in the formed holes, on the insulating layer 30a and on the insulating layer 30b on the surface of the circuit board 1. Then, the conductor formed on the insulating layer 30a and the insulating layer 30b is patterned into a predetermined wiring pattern shape by etching or the like. As a result, the conductor vias 40 to be connected to the electrode layers 12a and 12b are formed in the holes of the circuit board 1, and the conductor layer 50 (wiring) to be connected to the conductor vias 40 is formed on the insulating layer 30a and the insulating layer 30b.

By the step as illustrated in FIG. 7A, the circuit board 1A (FIG. 2) as described in the second embodiment is obtained. After forming the conductor via 40 and the conductor layer 50, for example, as illustrated in FIG. 7B, an insulating layer 70a and an insulating layer 70b are formed, and as illustrated in FIG. 7C, a conductor via 80 and a conductor layer 90 may be formed thereon.

Various insulating materials used as an insulating layer (interlayer insulating film) between the wiring layers of a multilayer circuit board are used for the insulating layer 70a and the insulating layer 70b. For example, for the insulating layer 70a and the insulating layer 70b, a resin material such as an epoxy resin, a polyimide resin, a bismaleimide triazine resin, or the like is used. As illustrated in FIG. 7B, the insulating layer 70a and the insulating layer 70b using such a material are formed on the insulating layer 30a and the insulating layer 30b which have been formed up to the formation of the conductor via 40 and the conductor layer 50. The thickness of the insulating layer 70a and the insulating layer 70b is, for example, 30 μm to 100 μm.

Then, conductor vias 80 and conductor layers 90 as illustrated in FIG. 7C are formed on the formed insulating layer 70a and insulating layer 70b. The conductor via 80 and the conductor layer 90 illustrated in FIG. 7C are formed as follows, for example. First, holes communicating with the conductor layer 50 are formed on the formed insulating layer 70a and the insulating layer 70b by laser processing. The diameter of the hole is, for example, 50 μm to 250 μm. Next, electroless plating or electrolytic plating is performed, and conductors are formed in the formed hole, and on the insulating layer 70a and the insulating layer 70b. Then, the conductor formed on the insulating layer 70a and the insulating layer 70b is patterned into a predetermined wiring pattern shape by etching or the like. As a result, the conductor via 80 to be connected to the lower conductor layer 50 (lower layer wiring) is formed in the holes of the insulating layer 70a and the insulating layer 70b, and the upper layer conductor layer 90 (upper layer wiring) to be connected to the conductor via 80 is formed on the insulating layer 70a and the insulating layer 70b.

A multilayer circuit board 1D including a plurality of wiring layers (conductor layers 50 and 90) may be obtained in addition to the capacitor 10 by the step illustrated in FIGS. 7B and 7C. By repeating the steps illustrated in FIGS. 7B and 7C a plurality of times, the circuit board 1D having a desired number of wiring layers may be obtained.

For example, in the multilayer circuit board 1D, as the insulating material of the insulating layer 30a and the insulating layer 30b, an insulating material having a higher elastic modulus than the insulating material used for the insulating layer 70a and the insulating layer 70b and the like provided thereon, for example, an insulating material having high rigidity and Young's modulus is used. By interposing the insulating layer 30a and the insulating layer 30b using such an insulating material between the insulating layer 70a, the insulating layer 70b, and the capacitor 10, the rigidity and strength of the circuit board 1D are increased, and damage to the capacitor 10 is effectively suppressed. In the circuit board 1D, since rigidity and strength are increased by the insulating layer 30a and the insulating layer 30b, for the insulating layer 70a and the insulating layer 70b and the like provided thereon, materials may be selected with more emphasis on electrical characteristics such as dielectric permittivity than mechanical characteristics such as rigidity thereof.

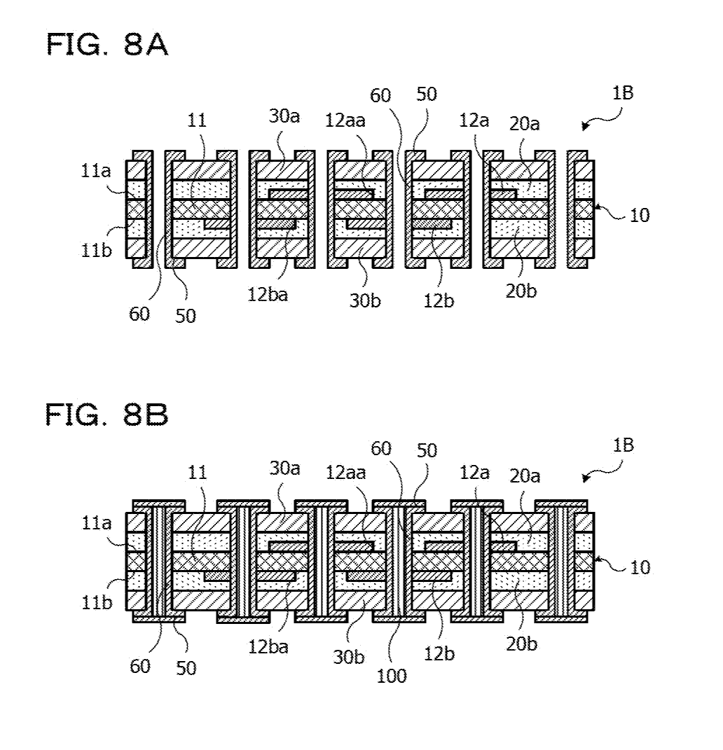

In addition, FIGS. 8 to 10 are diagrams illustrating another example of the method for forming the circuit board according to the fourth embodiment. FIGS. 8A and 8B, 9A and 9B, and 10A and 10B schematically illustrate a cross section of a main part of each step in another example of forming the circuit board according to the fourth embodiment, respectively.

For example, after the step of FIG. 6C, as illustrated in FIG. 8A, the conductor via 60 penetrating the non-overlapping portions of the electrode layer 12a and the electrode layer 12b, and the conductor via 60 penetrating portions where neither the electrode layer 12a nor the electrode layer 12b exist are formed.

In this case, for example, holes penetrating the respective portions are formed by drilling, electroless plating or electrolytic plating is applied, and conductors are formed on the inner wall of the formed holes, and on the insulating layer 30a and the insulating layer 30b. Then, the conductor formed on the insulating layer 30a and the insulating layer 30b is patterned into a predetermined wiring pattern shape by etching or the like. As a result, the circuit board 1B (FIG. 3) as described in the second embodiment including the conductor via 60 penetrating from the insulating layer 30a to the insulating layer 30b and the conductor layer 50 to be connected to the insulating layer 30a to the insulating layer 30b is obtained.

In forming the circuit board 1B, after formation of a hole by drilling, formation of a conductor by electroless plating or electrolytic plating, filling of the resin in the cavity remaining in the hole and plating of the lid may be performed and thereafter patterning of the conductor formed on the insulating layer 30a and the insulating layer 30b may be performed. According to such a method, as illustrated in FIG. 8B, the circuit board 1B in which the inside of the conductor via 60 is filled with a resin 100 is obtained.

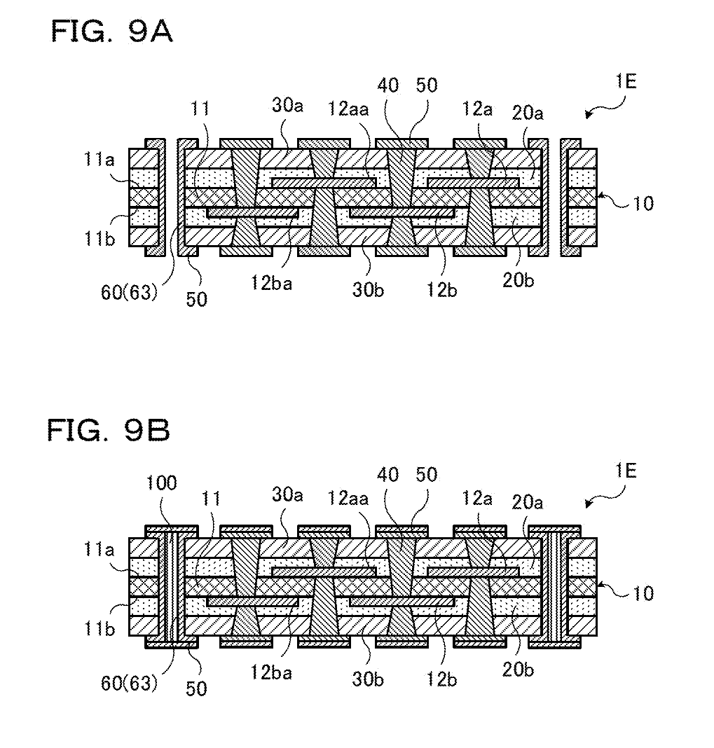

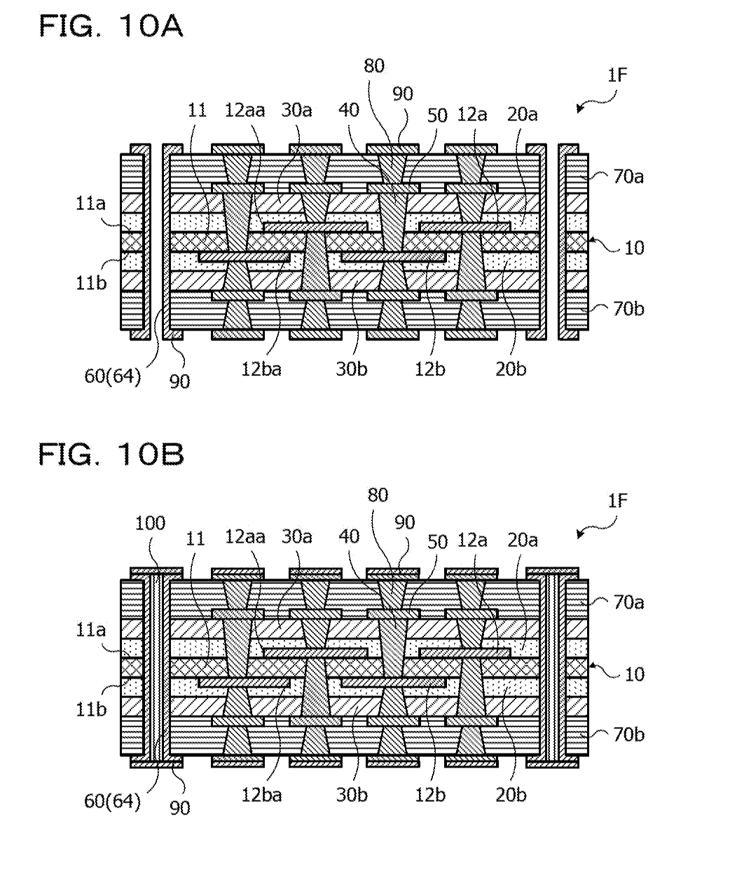

In addition, for example, a circuit board 1E as illustrated in FIGS. 9A and 9B, a circuit board 1F as illustrated in FIGS. 10A and 10B may be obtained. For example, in the case of obtaining the circuit board 1E as illustrated in FIGS. 9A and 9B, the following method is used. In the step of FIG. 7A, first, holes communicating with the electrode layer 12a and the electrode layer 12b are formed by laser processing, and the conductor vias 40 are formed in the holes. Next, as illustrated in FIG. 9A, holes penetrating from the insulating layer 30a to the insulating layer 30b are formed at portions where neither the electrode layer 12a nor the electrode layer 12b exists by drilling. Subsequently, electroless plating or electrolytic plating is performed, and conductors are formed on the inner wall of the formed holes, and on the insulating layer 30a and the insulating layer 30b. Then, the conductor formed on the insulating layer 30a and the insulating layer 30b is patterned into a predetermined wiring pattern shape by etching or the like. As a result, as illustrated in FIG. 9A, the circuit board 1E including the conductor via 40 to be connected to the electrode layer 12a and the electrode layer 12b, the conductor via 60 (conductor via 63) penetrating from the insulating layer 30a to the insulating layer 30b without being connected to the electrode layer 12a and the electrode layer 12b, and the conductor layers 50 to be connected to the insulating layer 30a to the insulating layer 30b is obtained.

In forming the circuit board 1E, after formation of a hole by drilling, formation of a conductor by electroless plating or electrolytic plating, filling of the resin in the cavity remaining in the hole and plating of the lid may be performed and thereafter patterning of the conductor formed on the insulating layer 30a and the insulating layer 30b may be performed. According to such a method, as illustrated in FIG. 9B, the circuit board 1E in which the inside of the conductor via 63 penetrating from the insulating layer 30a to the insulating layer 30b without being connected to the electrode layer 12a and the electrode layer 12b is filled with the resin 100 is obtained.

In addition, in the case of obtaining the circuit board 1F as illustrated in FIGS. 10A and 10B, the following method is used. In the step of FIG. 7C, first, holes that communicate with the conductor layer 50 are formed by laser processing on the insulating layers 70a and 70b, and the conductor vias 80 are formed in the holes. Next, as illustrated in FIG. 10A, holes penetrating from the insulating layer 70a to the insulating layer 70b are formed at portions where neither the electrode layer 12a nor the electrode layer 12b exists by drilling. Subsequently, electroless plating or electrolytic plating is performed, and conductors are formed on the inner wall of the formed holes, and on the insulating layer 70a and the insulating layer 70b. Then, the conductor formed on the insulating layer 70a and the insulating layer 70b is patterned into a predetermined wiring pattern shape by etching or the like. As a result, as illustrated in FIG. 10A, the circuit board 1F including the conductor via 80 to be connected to the conductor layer 50, the conductor via 60 (conductor via 64) penetrating from the insulating layer 70a to the insulating layer 70b without being connected to the electrode layer 12a and the electrode layer 12b, and the conductor layers 90 to be connected to the insulating layer 70a to the insulating layer 70b is obtained.

In forming the circuit board 1F, after formation of a hole by drilling, formation of a conductor by electroless plating or electrolytic plating, filling of the resin in the cavity remaining in the hole and plating of the lid may be performed and thereafter patterning of the conductor formed on the insulating layer 70a and the insulating layer 70b may be performed. According to such a method, as illustrated in FIG. 10B, the circuit board 1F in which the inside of the conductor via 64 penetrating from the insulating layer 70a to the insulating layer 70b without being connected to the electrode layer 12a and the electrode layer 12b is filled with the resin 100 is obtained.

In addition, the circuit board 1C as illustrated in FIG. 4 may be obtained by the following method. Before bonding of the insulating layer 30a by the adhesive layer 20a illustrated in FIG. 6C, a separately prepared capacitor 10C is bonded onto the capacitor 10 with the adhesive layer 20c, and the insulating layer 30a is bonded to the capacitor 10C with the adhesive layer 20a. As a result, a structure is obtained in which the capacitor 10 and the capacitor 10C bonded with the adhesive layer 20c are sandwiched between the insulating layer 30a and the insulating layer 30b with the adhesive layer 20a and the adhesive layer 20b interposed therebetween. In contrast to this structure, by forming holes by drilling, forming conductors, patterning, and the like according to the above example, the circuit board 1C (FIG. 4) described in the third embodiment may be obtained.

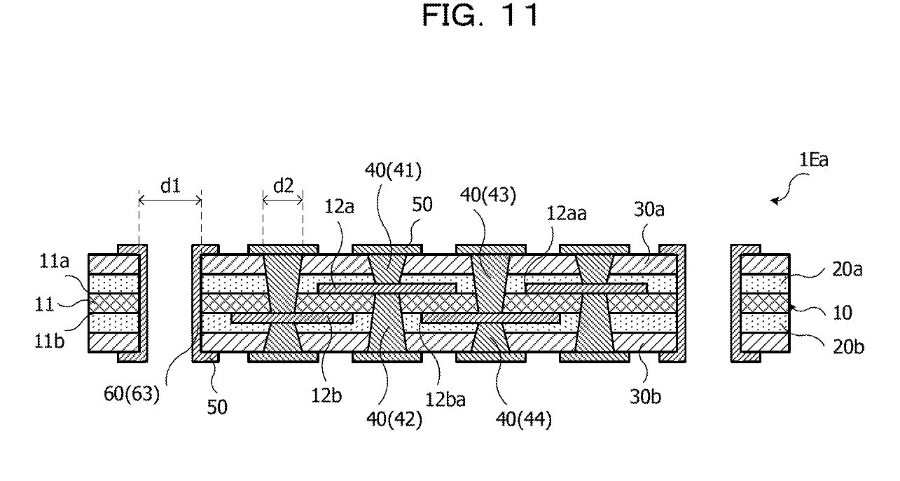

Next, a fifth embodiment will be described. FIG. 11 is a diagram illustrating a first example of a circuit board according to the fifth embodiment. FIG. 11 schematically illustrates a cross section of a main part of the first example of the circuit board according to the fifth embodiment.

The circuit board 1Ea illustrated in FIG. 11 is an example of a circuit board whose basic structure is the circuit board 1 (FIG. 1) in which the capacitor 10 is sandwiched between the insulating layer 30a and the insulating layer 30b having a higher elastic modulus than the adhesive layer 20a and the adhesive layer 20b via the adhesive layer 20a and the adhesive layer 20b.

The circuit board 1Ea includes the conductor via 40 to be connected to the electrode layer 12a and the electrode layer 12b, the conductor via 60 penetrating from the insulating layer 30a to the insulating layer 30b without being connected to the electrode layer 12a and the electrode layer 12b, and the conductor layer 50 to be connected to the insulating layer 30a to the insulating layer 30b. In FIG. 11, the conductor via 41, the conductor via 42, the conductor via 43, and the conductor via 44 are illustrated as the conductor via 40 to be connected to the electrode layer 12a and the electrode layer 12b, and the conductor via 63 is illustrated as the conductor via 60 not connected to the electrode layer 12a and the electrode layer 12b. The inside of the conductor via 63 may be filled with the resin 100 according to the example of FIG. 9B.

In the circuit board 1Ea, the diameter d1 of the conductor via 63 not connected to the electrode layer 12a and the electrode layer 12b is larger than a diameter d2 of each of the conductor vias 41 to 44 to be connected to the electrode layer 12a and the electrode layer 12b.

By making the diameter d2 of each of the conductor vias 41 to 44 to be connected to the electrode layer 12a and the electrode layer 12b relatively small as described above, portions where the conductor via 42 to be connected to the electrode layer 12a and the conductor via 43 to be connected to the electrode layer 12b penetrates the dielectric layer 11 are suppressed from becoming large. Further, the size of the opening 12ba provided in the electrode layer 12b for forming the conductor via 42 and the size of the opening 12aa provided in the electrode layer 12a for forming the conductor via 43 are suppressed from becoming large. As a result, it is possible to suppress a reduction in electrostatic capacitance caused by providing a large number of portions (portions where the dielectric layer 11 is sandwiched between the electrode layer 12a and the electrode layer 12b) functioning as capacitors inside the capacitor 10 and providing the conductor vias 41 to 44.

On the other hand, for the conductor via 63 not connected to the electrode layer 12a and the electrode layer 12b, increasing the diameter d1 facilitates the formation of a conductor in the hole during plating and suppresses formation defects (occurrence of a portion where conductors are not formed and very thin portions, and the like). As a result, it is possible to secure conduction between the front and back surfaces and to cope with a large current.

By the high elastic modulus insulating layer 30a and the insulating layer 30b respectively bonded to the capacitor 10 with the adhesive layer 20a and the adhesive layer 20b, the conductor vias 41 to 44 whose diameter d2 is adjusted, and the conductor via 63 whose diameter d1 is adjusted, the circuit board 1Ea having excellent performance and reliability is realized.

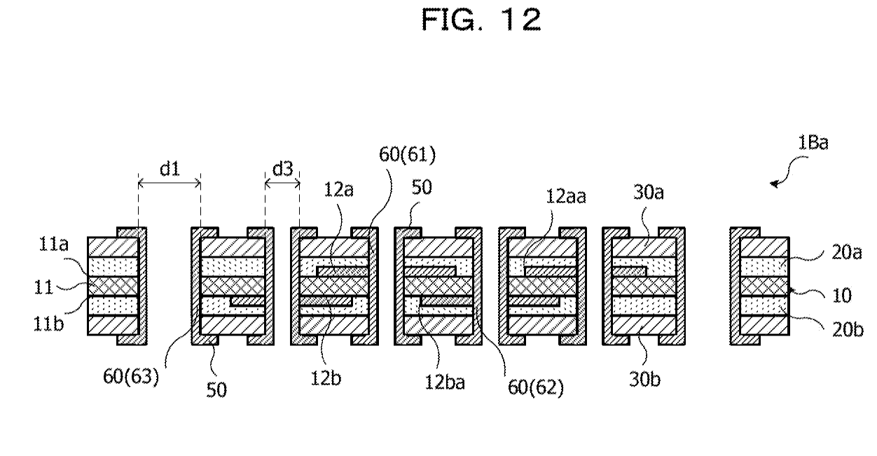

FIG. 12 is a diagram illustrating a second example of the circuit board according to the fifth embodiment. FIG. 12 schematically illustrates a cross section of a main part of the second example of the circuit board according to the fifth embodiment. The circuit board 1Ba illustrated in FIG. 12 is an example of a circuit board whose basic structure is the circuit board 1 (FIG. 1) in which the capacitor 10 is sandwiched between the insulating layer 30a and the insulating layer 30b having a higher elastic modulus than the adhesive layer 20a and the adhesive layer 20b via the adhesive layer 20a and the adhesive layer 20b.

The circuit board 1Ba includes the conductor via 60 penetrating the non-overlapping portions of the electrode layer 12a and the electrode layer 12b, the conductor via 60 penetrating portions where neither the electrode layer 12a nor the electrode layer 12b exists, and the conductor layer 50 to be connected to the electrode layer 12a and the electrode layer 12b. In FIG. 12, the conductor via 61 and the conductor via 62 are illustrated as the conductor vias 60 penetrating non-overlapping portions of the electrode layers 12a and 12b, and the conductor vias 63 are illustrated as the conductor vias 60 penetrating the portions where neither the electrode layer 12a nor the electrode layer 12b exists. The inside of the conductor via 63 may be filled with the resin 100 according to the example of FIG. 8B.

In the circuit board 1Ba, the diameter d1 of the conductor via 63 not connected to the electrode layer 12a and the electrode layer 12b is larger than a diameter d3 of each of the conductor via 61 and the conductor via 62 to be connected to the electrode layer 12a and the electrode layer 12b.

By making the diameter d3 of each of the conductor via 61 and the conductor via 62 to be connected to the electrode layer 12a and the electrode layer 12b relatively small as described above, portions where the conductor via 61 and the conductor via 62 penetrates the dielectric layer 11 are suppressed from becoming large. Further, the size of the opening 12ba provided in the electrode layer 12b for forming the conductor via 61 and the size of the opening 12aa provided in the electrode layer 12a for forming the conductor via 62 are suppressed from becoming large. As a result, it is possible to suppress a reduction in electrostatic capacitance caused by providing a large number of portions (portions where the dielectric layer 11 is sandwiched between the electrode layer 12a and the electrode layer 12b) functioning as capacitors inside the capacitor 10 and providing the conductor via 61 and the conductor via 62.

On the other hand, for the conductor via 63 not connected to the electrode layer 12a and the electrode layer 12b, increasing the diameter d1 facilitates the formation of a conductor in the hole during plating and suppresses formation defects (occurrence of a portion where conductors are not formed and very thin portions, and the like). As a result, it is possible to secure conduction between the front and back surfaces and to cope with a large current.

By the high elastic modulus insulating layer 30a and the insulating layer 30b respectively bonded to the capacitor 10 with the adhesive layer 20a and the adhesive layer 20b, the conductor vias 61 and 62 whose diameter d3 is adjusted, and the conductor via 63 whose diameter d1 is adjusted, the circuit board 1Ba having excellent performance and reliability is realized.

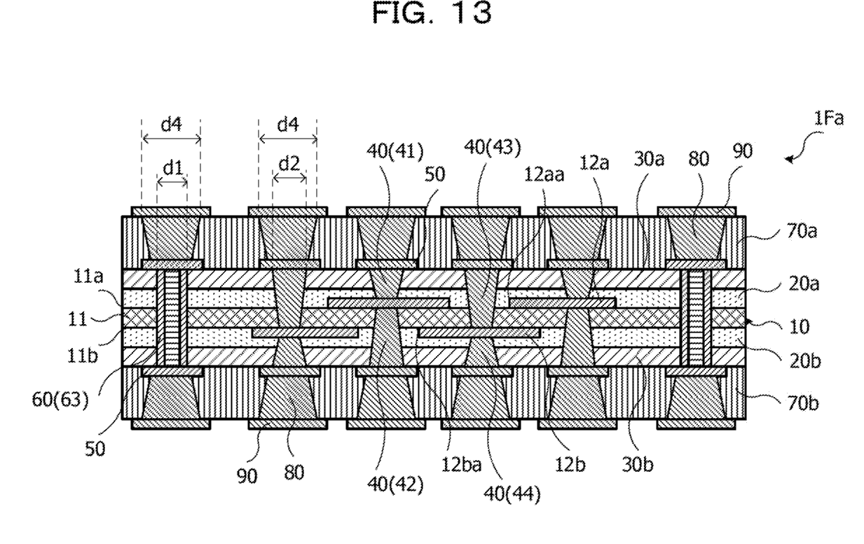

FIG. 13 is a diagram illustrating a third example of the circuit board according to the fifth embodiment. FIG. 13 schematically illustrates a cross section of a main part of the third example of the circuit board according to the fifth embodiment. A circuit board 1Fa illustrated in FIG. 13 has a structure in which the insulating layer 70a and the insulating layer 70b are respectively provided on the insulating layer 30a and the insulating layer 30b of the circuit board 1Ea illustrated in FIG. 11 and the conductor via 80 and the conductor layer 90 are respectively provided in the insulating layer 70a and the insulating layer 70b.

In the circuit board 1Fa, the diameter d4 of the conductor via 80 to be connected to the conductor layer 70a and the conductor layer 70b is larger than a diameter d1 of the conductor via 60 (conductor via 63) not connected to the electrode layer 12a and the electrode layer 12b. Further, in a circuit board 1Fa, the diameter d4 of the conductor via 80 to be connected to the conductor layer 70a and the conductor layer 70b is larger than the diameter d2 of each conductor via 40 (conductor vias 41 to 44) to be connected to the electrode layer 12a and the electrode layer 12b. The diameter d1 of the conductor via 63 not connected to the electrode layer 12a and the electrode layer 12b may be larger than a diameter d2 of each of the conductor vias 41 to 44 to be connected to the electrode layer 12a and the electrode layer 12b or may be the same as the diameter d2.

By making the diameter d2 of each of the conductor vias 41 to 44 to be connected to the electrode layer 12a and the electrode layer 12b relatively small, a large portion (a portion where the dielectric layer 11 is sandwiched between the electrode layer 12a and the electrode layer 12b) is left in the capacitor 10 that functions as a capacitor. As a result, it is possible to suppress the decrease in electrostatic capacitance due to the provision of the conductor vias 41 to 44.

Further, it is possible to secure electrical connection and improve mechanical strength by connecting the conductor via 80 having the relatively large diameter d4 on the conductor via 63 having the relatively small diameter d1 and on the conductor vias 41 to 44 having the relatively small diameter d2. Particularly, in the conductor via 63 filled with the resin 100 on the inside, it is possible to suppress the thermal expansion of the resin 100 with the conductor via 80 having the relatively large diameter d4 to suppress peeling and disconnection of the conductor layer 50 on the conductor via 63.

By the high elastic modulus insulating layer 30a and the insulating layer 30b respectively bonded to the capacitor 10 with the adhesive layer 20a and the adhesive layer 20b, the conductor via 80 whose diameter d4 is adjusted, and the conductor vias 63, and 41 to 44 whose diameter d1 and d2 are adjusted, the circuit board 1Fa having excellent performance and reliability is realized.

Even in a circuit board in which the insulating layer 70a and the insulating layer 70b are respectively provided on the insulating layer 30a and the insulating layer 30b of the circuit board 1Ba illustrated in FIG. 12 and the conductor via 80 and the conductor layer 90 are respectively provided in the insulating layer 70a and the insulating layer 70b, the same configuration may be obtained. That is, the diameter d4 of the conductor via 80 to be provided in the insulating layer 70a and the insulating layer 70b has a value larger than the diameter d1 of the conductor via 63 not connected to the electrode layer 12a and the electrode layer 12b. Further, the diameter d4 of the conductor via 80 to be provided in the insulating layer 70a and the insulating layer 70b has a value larger than the diameter d3 of each of the conductor via 61 and the conductor via 62 to be connected to the electrode layer 12a and the electrode layer 12b. It is possible to secure electrical connection and improve mechanical strength by providing the conductor via 61 and the conductor via 62 having the relatively small diameter d3, the reduction in the electrostatic capacitance of the capacitor 10 may be suppressed, and by providing the conductor via 80 having the relatively large diameter d4. Particularly, in the conductor vias 61 to 63 filled with the resin 100 inside, the thermal expansion of the resin 100 is suppressed by the conductor via 80 having the relatively large diameter d4, and peeling off or disconnection of the conductor layer 50 on the conductor vias 61 to 63 is suppressed.

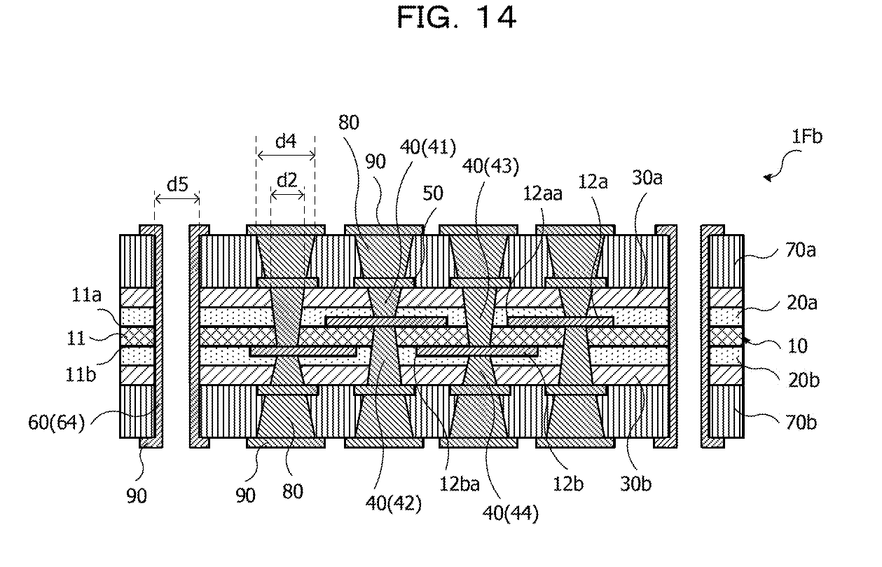

FIG. 14 is a diagram illustrating a fourth example of the circuit board according to the fifth embodiment. FIG. 14 schematically illustrates a cross section of a main part of the fourth example of the circuit board according to the fifth embodiment. In a circuit board 1Fb illustrated in FIG. 14, the diameter d4 of the conductor via 80 to be connected to the conductor layer 50 is larger than the diameter d2 of each conductor via 40 (conductor vias 41 to 44) to be connected to the electrode layer 12a and the electrode layer 12b. Further, in the circuit board 1Fb, the diameter d4 of the conductor via 80 to be connected to the conductor layer 50 is larger than a diameter d5 of the conductor via 60 (conductor via 64) not connected to the electrode layer 12a and the electrode layer 12b. The diameter d5 of the conductor via 64 not connected to the electrode layer 12a and the electrode layer 12b may be larger than the diameter d2 of each of the conductor vias 41 to 44 to be connected to the electrode layer 12a and the electrode layer 12b or may be the same as the diameter d2. The inside of the conductor via 64 may be filled with the resin 100 according to the example of FIG. 10B.

By making the diameter d2 of each of the conductor vias 41 to 44 to be connected to the electrode layer 12a and the electrode layer 12b relatively small, a large portion (a portion where the dielectric layer 11 is sandwiched between the electrode layer 12a and the electrode layer 12b) is left in the capacitor 10 that functions as a capacitor. As a result, it is possible to suppress the decrease in electrostatic capacitance due to the provision of the conductor vias 41 to 44.

By the insulating layer 30a and the insulating layer 30b having a high elastic modulus and respectively bonded to the capacitor 10 with the adhesive layer 20a and the adhesive layer 20b, the conductor via 80 whose diameter d4 is adjusted, and the conductor vias 41 to 44, and 64 whose diameter d2 and d5 are adjusted, the circuit board 1Fb having excellent performance and reliability is realized.

Next, a sixth embodiment will be described. Various electronic components including semiconductor apparatuses such as semiconductor chips and semiconductor packages may be mounted on the circuit board as described in the first to fifth embodiments.

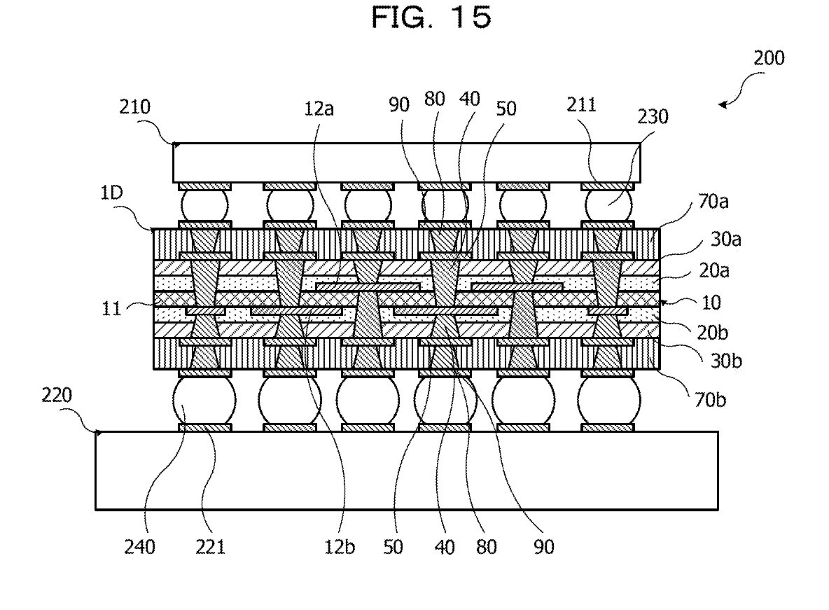

FIG. 15 is a diagram illustrating an example of an electronic device according to the sixth embodiment. FIG. 15 schematically illustrates a cross section of a main part of an example of an electronic device according to the fifth embodiment. Here, the circuit board 1D described in the fourth embodiment is taken as an example. An electronic device 200 illustrated in FIG. 15 includes a circuit board 1D and an electronic component 210 mounted on the circuit board 1D. The electronic device 200 has a configuration in which the circuit board 1D on which the electronic component 210 is mounted is further mounted on a circuit board 220.

The electronic component 210 is, for example, a semiconductor chip or a semiconductor package including a semiconductor chip. Such the electronic component 210 is mounted on the circuit board 1D. The conductor layer 90 (terminal) provided on the mounting surface side of the electronic component 210 of the circuit board 1D, and the conductor layer 211 (terminal) provided on the electronic component 210 are connected to each other via a bump 230 using solder or the like. As a result, the electronic component 210 and the circuit board 1D are electrically connected.

The circuit board 1D on which the electronic component 210 is mounted as described above is further mounted on the circuit board 220. The circuit board 220 is, for example, a printed circuit board. The conductor layer 90 (terminal) provided on the circuit board 220 side of the circuit board 1D and the conductor layer 221 (terminal) provided on the circuit board 220 are bonded via a bump 240 using solder or the like. As a result, the circuit board 1D on which the electronic component 210 is mounted is electrically connected to the circuit board 220.

In the electronic device 200, power is supplied from the circuit board 220 to the electronic component 210 via the bump 240, the circuit board 1D, and the bump 230. On the power supply line from the circuit board 220 to the electronic component 210, the capacitor 10 incorporated in the circuit board 1D is inserted while one of the electrode layer 12a and the electrode layer 12b is set to the power supply potential while the other (for example, the electrode layer 12b) is set to the GND potential. By inserting the capacitor 10 on the power supply line, the reduction of the power supply impedance, fluctuation of the power supply voltage, generation of high-frequency noise may be suppressed, and stable operation of the electronic component 210 is realized.

In the circuit board 1D, the capacitor 10 is sandwiched between the insulating layer 30a and the insulating layer 30b via the adhesive layer 20a and the adhesive layer 20b, and the rigidity and strength are increased. As a result, damage of the capacitor 10 due to stress caused by heat, such as during formation, use, test, and the like is suppressed, and the circuit board 1D having excellent performance and reliability is realized. By using such the circuit board 1D, the electronic device 200 having excellent performance and reliability against heat is realized.

Here, the electronic device 200 using the circuit board 1D described in the fourth embodiment has been illustrated. In addition, electronic devices using other circuit boards 1, 1A, 1B, 1Ba, 1C, 1E, 1Ea, 1F, 1Fa, 1Fb, and the like described in the first to fifth embodiments may be realized in the same manner.

Next, a seventh embodiment will be described. The circuit board as described in the first to fifth embodiments or an electronic device obtained by using such the circuit board may be mounted in various kinds of electronic apparatus. For example, it is possible to mount the circuit board on various kinds of electronic apparatus such as a computer (personal computer, super computer, server, and the like), a smartphone, a mobile phone, a tablet terminal, a sensor, a camera, audio equipment, a measuring apparatus, an inspection apparatus, a manufacturing apparatus, and the like.

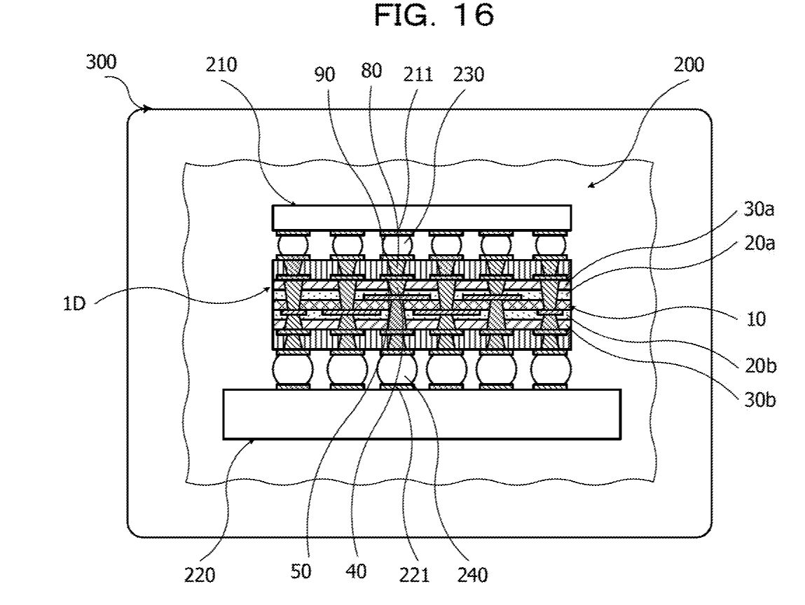

FIG. 16 is an explanatory diagram of an electronic apparatus according to the seventh embodiment. FIG. 16 schematically illustrates an example of the electronic apparatus. As illustrated in FIG. 16, for example, the electronic device 200 (FIG. 15) as described in the sixth embodiment is mounted (incorporated) in various kinds of an electronic apparatus 300.

In the electronic device 200B, since the capacitor 10 of the circuit board 1D is sandwiched between the insulating layer 30a and the insulating layer 30b via the adhesive layer 20a and the adhesive layer 20b to increase the rigidity and strength, damage to the capacitor 10 is suppressed. As a result, the electronic device 200 having excellent performance and reliability is realized, and the electronic apparatus 300 having such the electronic device 200 and having excellent reliability and performance is realized.

Here, the electronic apparatus 300 described in the sixth embodiment, in which the electronic device 200 using the circuit board 1D is mounted, has been illustrated. In addition, similarly, electronic devices using other circuit boards 1, 1A, 1B, 1Ba, 1C, 1E, 1Ea, 1F, 1Fa, 1Fb, and the like described in the first to fifth embodiments may be mounted on various kinds of electronic apparatus.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A circuit board comprising:
a first capacitor that includes a first dielectric layer, a first conductor layer disposed on a first surface of the first dielectric layer, and a second conductor layer disposed on a second surface of the first dielectric layer opposite to the first surface;
a first insulating layer that is bonded to the first surface side with a first adhesive layer and has a higher elastic modulus than the first adhesive layer; and
a second insulating layer that is bonded to the second surface side with a second adhesive layer and has a higher elastic modulus than the second adhesive layer.

2. The circuit board according to claim 1,
wherein glass is used for the first insulating layer and the second insulating layer.

3. The circuit board according to claim 1,
wherein a polyimide resin is used for the first insulating layer and the second insulating layer.

4. The circuit board according to claim 1,
wherein an epoxy resin is used for the first adhesive layer and the second adhesive layer.

5. The circuit board according to claim 1,
wherein the first adhesive layer bonds the first insulating layer and the first capacitor, and
the second adhesive layer bonds the second insulating layer and the first capacitor.

6. The circuit board according to claim 1, further comprising:
a second capacitor that is disposed between the first capacitor and the first adhesive layer and includes a second dielectric layer, a third conductor layer disposed on a third surface of the second dielectric layer, and a fourth conductor layer disposed on a fourth surface of the second dielectric layer opposite to the third surface; and
a third adhesive layer that bonds the first capacitor and the second capacitor.

7. The circuit board according to claim 1, further comprising:
a third insulating layer that is disposed on the first insulating layer and has a lower elastic modulus than the first insulating layer; and
a fourth insulating layer that is disposed on the second insulating layer and has a lower elastic modulus than the second insulating layer.

8. The circuit board according to claim 1, further comprising:
a first conductor via that is connected to the first conductor layer or the second conductor layer; and
a second conductor via that is not connected to the first conductor layer and the second conductor layer and has a larger diameter than the first conductor via.

9. The circuit board according to claim 1, further comprising:
a first conductor via that is connected to the first conductor layer or the second conductor layer;
a fifth insulating layer that is disposed on the first insulating layer; and
a third conductor via that is disposed in the fifth insulating layer and has a larger diameter than the first conductor via.

10. A method of manufacturing a circuit board, the method comprising:
bonding a first insulating layer having a higher elastic modulus than a first adhesive layer to a first surface side with the first adhesive layer, the first surface being in a capacitor including a dielectric layer, a first conductor layer disposed on the first surface of the dielectric layer, and a second conductor layer disposed on a second surface of the dielectric layer opposite to the first surface; and
bonding a second insulating layer having a higher elastic modulus than the second adhesive layer to the second surface side with a second adhesive layer.

11. An electronic device comprising:
a circuit board, the circuit board including
a capacitor that includes a dielectric layer, a first conductor layer disposed on a first surface of the dielectric layer, and a second conductor layer disposed on a second surface of the dielectric layer opposite to the first surface,
a first insulating layer that is bonded to the first surface side with a first adhesive layer and has a higher elastic modulus than the first adhesive layer, and
a second insulating layer that is bonded to the second surface side with a second adhesive layer and has a higher elastic modulus than the second adhesive layer; and
an electronic component mounted on the circuit board.
